(19) United States
(12) Patent Application Publication
(10) Pub. No.: US 2023/0223277 A1
(43) Pub. Date: Jul. 13, 2023

(54) CHIP CARRIER

(71) Applicant: STMicroelectronics (Grenoble 2) SAS, Grenoble (FR)

(72) Inventors: Fanny LAPORTE, Villaz (FR); Ludovic FOURNEAUD, Saint Vincent de Mercuze (FR); Eric SAUGIER, Froges (FR)

(73) Assignee: STMicroelectronics (Grenoble 2) SAS, Grenoble (FR)

(21) Appl. No.: 18/094,775

(22) Filed: Jan. 9, 2023

(30) Foreign Application Priority Data
Jan. 11, 2022 (FR) 2200190

(51) Int. Cl. H01L 21/48; H01L 23/13; H01L 23/498

(52) U.S. Cl. CPC H01L 21/4857; H01L 21/486; H01L 23/13; H01L 23/49838; H01L 24/48

(57) ABSTRACT

An integrated circuit chip carrier includes a wall surrounding a cavity. The wall includes one or more levels where each level is formed from a layer of a resin around a block. The block is made of a material different from the resin. The block is removed to open the cavity.

### PRIORITY CLAIM

This application claims the priority benefit of French Application for Patent No. 2200190, filed on Jan. 11, 2022, the content of which is hereby incorporated by reference in its entirety to the maximum extent allowable by law.

### TECHNICAL FIELD

The present disclosure generally concerns electronic devices and, more specifically, electronic chip carriers.

### BACKGROUND

Electronic integrated circuit chips are present in many electronic devices. Such chips are often placed, during one or a plurality of manufacturing steps or during their operation, in a carrier structure comprising a cavity, the chip being located in the cavity.

There is a need in the art to overcomes all or part of the disadvantages of known chip carriers.

### SUMMARY

An embodiment provides a method of manufacturing a carrier comprising a cavity, comprising: forming a wall surrounding the cavity, the wall comprising at least one first level, wherein forming each first level comprises forming a layer of a first resin around a first block, the first block being made of a material different from the first resin, and removing the first block(s).

According to an embodiment, the method comprises: forming a base of the carrier having the wall resting thereon, wherein forming the base comprises forming at least one second level, wherein forming each second level comprises forming a layer of a first resin extending in front of the location of the cavity.

According to an embodiment, forming the base comprises forming metal vias crossing the base in front of the cavity.

According to an embodiment, forming at least certain levels comprises growing metal tracks and metal vias.

According to an embodiment, the first block(s) are made of the same material as the tracks and vias.

According to an embodiment, the levels are formed on an at least partially metallic plate.

According to an embodiment, the second levels are formed on the at least partially metallic plate before forming the first levels.

According to an embodiment, the at least partially metallic plate forms the base of the carrier.

According to an embodiment, the first levels are formed on the at least partially metallic plate before forming the second levels.

According to an embodiment, the first block(s) are formed by a portion of the at least partially metallic plate.

According to an embodiment, the wall comprises a plurality of levels and all the first blocks have same horizontal dimensions.

According to an embodiment, at least one sidewall of at least one first block is inclined with respect to the plane of the back of the cavity.

According to an embodiment, the first blocks of the first levels closest to the back of the cavity have at least one horizontal dimension smaller than that of the first blocks in the other first levels.

According to an embodiment, the method comprises filling of the cavity with a second resin different from the first resin.

Another embodiment provides a device obtained by the method such as previously described, the cavity having a height greater than 30 µm.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 shows an embodiment of an electronic chip carrier;

FIG. 2 shows an example of application of the embodiment of FIG. 1;

FIG. 3 shows another example of the embodiment of FIG. 1;

FIGS. 4A to 4D show steps of an implementation mode of a method of manufacturing the embodiment of FIG. 1;

FIGS. 5A to 5C show steps of another implementation mode of a method of manufacturing the embodiment of FIG. 1;

FIG. 6 shows another embodiment of an electronic chip carrier;

FIG. 7 shows another embodiment of an electronic chip carrier;

FIG. 8 shows another embodiment of an electronic chip carrier;

FIG. 9 shows another embodiment of an electronic chip carrier;

FIG. 10 shows another embodiment of an electronic chip carrier; and

FIG. 11 shows another embodiment of an electronic chip carrier.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

FIG. 1 shows an embodiment of an electronic integrated circuit chip carrier 10.

Carrier 10 comprises a lower portion, or base, 12. Base 12 comprises one or a plurality of resin layers.

In the embodiment of FIG. 1, base 12 is exclusively formed of said resin. Base 12 thus only comprises one or a plurality of layers entirely made of said resin.

The resin forming the base is, for example, an epoxy resin, for example a thermosetting molding resin. For example, said resin is a black resin. For example, said resin is a resin opaque for at least certain wavelengths, for example visible wavelengths, that is, for example, wavelengths in the range from 380 nm to 780 nm.

Carrier 10 further comprises a lateral wall 14 or upper portion. Wall 14 rests on base 12, more precisely on an upper surface of base 12. Wall 14 extends on the periphery of base 12. Preferably, the upper surface of base 12 is divided into a central portion and a peripheral portion surrounding the central portion, with lateral wall 14 resting on the peripheral portion, preferably on the entire peripheral portion.

Thus, wall 14 forms (or delimits) a cavity 16. Cavity 16 is, for example, intended to receive an integrated circuit chip, not shown. Cavity 16 is located in front of the central portion of the upper surface of base 12. In other words, the upper surface of base 12, and in particular the central portion, forms a bottom, the back, of cavity 16. Walls 14, and more precisely inner surfaces of walls 14, form sidewalls of cavity 16. Further, cavity 16 is open.

Wall 14 is formed of one or a plurality of resin layers, preferably the same resin as the resin forming the layer(s) of base 12. Thus, wall 14 comprises one or a plurality of resin layers, for example made of epoxy resin, for example a black resin, for example a thermosetting molding resin.

Each layer of wall 14 may comprise metal tracks 18 and metal vias 20, for example, copper tracks and vias. Conductive tracks 22, for example, rest on the upper surface of wall 14. For example, each track 22 rests in contact with an end of a via 18 flush with the upper surface of wall 14. Tracks 18, 22 and vias 20 form an interconnection network.

As a variant, tracks 22 may be located in a resin layer and may be flush with the upper surface of wall 14.

Preferably, wall 14 has a height, that is, the distance between the upper surface of base 12 and the upper surface of wall 14, greater than the height of the integrated circuit chip intended to be placed in the cavity.

The height of wall 14, that is, the height of cavity 16, is for example greater than 30 µm, for example greater than 700 µm, for example greater than 1 mm. The height of wall 14 is, for example, smaller than 2 mm.

As a variant, base 12 may comprise, in addition to the resin layer(s), metal tracks and metal vias, not shown, such as tracks 18 and vias 20.

The different resin layers forming base 12 and/or wall 14, for example, have a same height. However, one or a plurality of levels may have different heights. In the example of FIG. 1, all the levels have the same height.

The carrier 10 of FIG. 1 comprises four levels N1, N2, N3, and N4. Base 12 comprises levels N4 and N3, N4 being the level most distant from wall 14, and wall 14 comprises levels N1 and N2, level N1 being the level most distant from the base. In the example of FIG. 1, levels N4 and N3 are entirely made of resin.

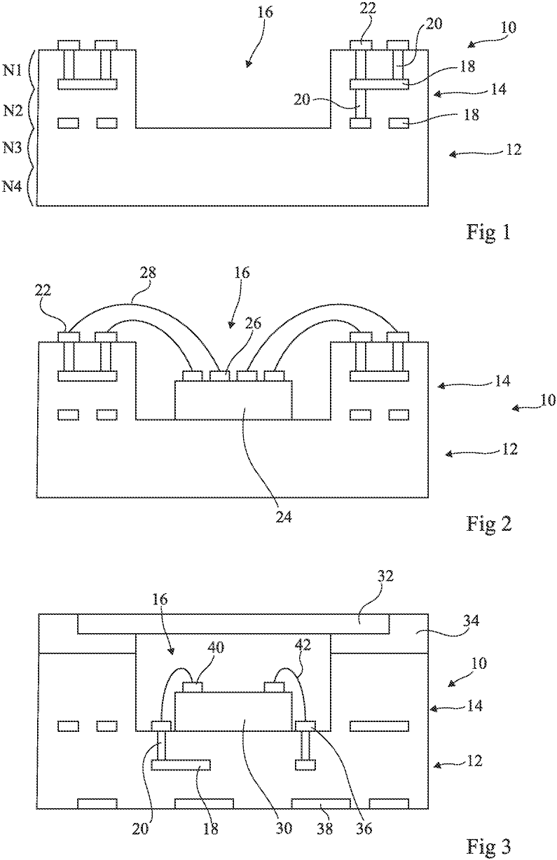

FIG. 2 shows an example of application of the embodiment of FIG. 1.

In the example of FIG. 2, carrier 10 is used as a test structure for an integrated circuit chip 24. Chip 24 is placed in cavity 16. Chip 24 rests on the upper surface of base 12. Chip 24 is surrounded by wall 14. Chip 24 is, for example, bonded to the back of the cavity by a bonding layer, not shown.

Chip 24 comprises, for example, connection pads 26, for example located on the upper surface of chip 24. Pads 26 are coupled to tracks 22 by electric wires 28. Thus, test signals may be supplied to chip 24 via carrier 10.

FIG. 3 shows another example of the embodiment of FIG. 1.

In the example of FIG. 3, carrier 10 is used as a portion of an optoelectronic device package. An optoelectronic integrated circuit chip 30 is located in cavity 16. Chip 30 comprises, for example, a light emitter and/or receiver. Preferably, the resin forming carrier 10 is opaque to the wavelengths of operation of chip 30.

The device comprises, in this application, a plate 32, preferably transparent to the operating wavelengths of chip 30. Plate 32 is, for example, made of glass. Plate 32 closes cavity 16. Plate 32 is thus positioned at least in front of the central portion of the upper surface of the base. Plate 32 rests on the upper surface of wall 14. Plate 32 is bonded to the upper surface of wall 14, for example, by a bonding element 34, for example, glue.

In the example of FIG. 3, base 12 comprises metal tracks 18 and metal vias 20. The tracks 18 and the vias 20 of base 12 enable to couple tracks 36 located in cavity 16 to tracks 38 located at the level of the lower surface of the base, for example, flush with the lower surface of the base.

Chip 30, for example, has connection pads 40 coupled to tracks 36 by electric wires 42.

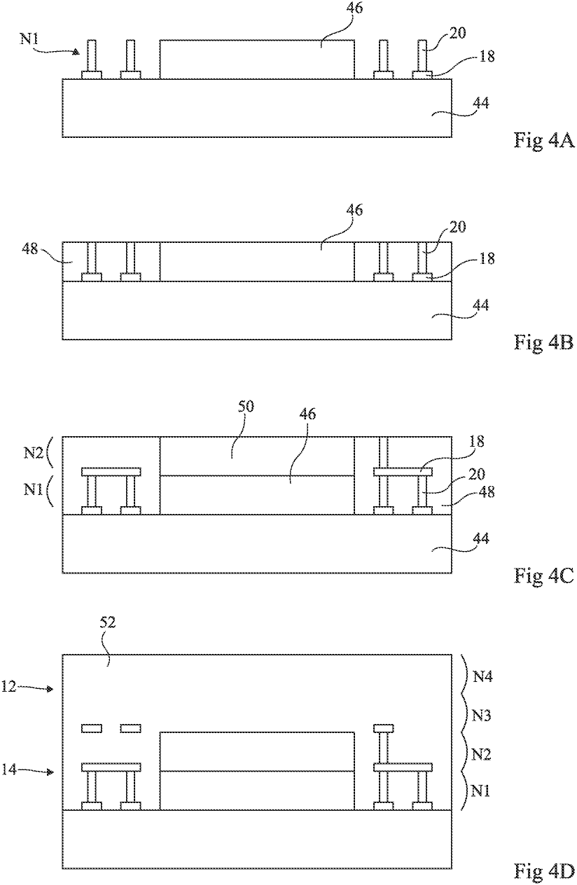

FIGS. 4A to 4D show steps, preferably successive, of an implementation mode of a method of manufacturing the embodiment of FIG. 1. Steps 4A to 4C show the forming of wall 14. Step 4D shows the forming of base 12. Although FIGS. 4A to 4D show the forming of a single carrier 10, the method, for example, enables simultaneous production of a plurality of carriers 10.

FIG. 4A shows a step of an implementation mode of a method of manufacturing the embodiment of FIG. 1.

During this step, the tracks 18 and the vias 20 of a level N1 are formed on a plate 44, for example, a metal plate. The step of FIG. 4A thus comprises the growth of the metal tracks and vias from plate 44. Tracks 18 and vias 20 are, for example, made of copper.

Tracks 18 and vias 20 correspond to the tracks and to the vias of the level N1 of the carrier 10 of FIG. 1, that is, the upper level, most distant from the base.

A block 46 is bonded to plate 44. Block 46, for example, has a cuboid shape. Block 46 is located at the location of cavity 16 in level N1. Block 46 is, for example, bonded to plate 16 by a bonding layer, for example, a glue layer. The dimensions of block 46 are substantially equal to the dimensions of the portion of cavity 16 in level N1. In particular, the height of block 46 is substantially equal, preferably equal, to the height of level N1.

Block 46 is, for example, made of resin, of plastic, or of metal. Block 46 is made of a material different from the resin forming carrier 10. Block 46 is preferably made of a material which does not bond to the resin.

FIG. 4B shows another step of an implementation mode of a method of manufacturing the embodiment of FIG. 1.

During this step, the resin, for example in liquid form, is placed on plate 46 to form a resin layer 48. The quantity of resin used is sufficient for tracks 18, vias 20, and block 46 to be buried in the resin. Thus, the thickness of the resin layer is greater than the height of level N1 and is thus greater than the height of block 46.

The resin is then heated so that it becomes solid. The resin is thinned, for example, by a chemical-mechanical polishing method, so that the height of the layer is equal to the height of level N1. The thinning of the resin is performed so that the ends of vias 20 and the upper surface of block 46, that is, the surface most distant from plate 44, are flush with the upper surface of layer 48.

FIG. 4C shows another step of an implementation mode of a method of manufacturing the embodiment of FIG. 1.

During this step, level N2 is formed. The steps of FIGS. 4A and 4B are carried out on the previously-formed level, that is, on level N1, to form level N2. In other words, the step of FIG. 4C comprises the forming, by growth on level N1, of the tracks 18 and of the vias 20 of level N2, the placing of a block 50 at the location of cavity 16 in level N2, the forming of the resin layer of level N2. Block 50 is preferably made of the same material as block 46. Block 50, for example, has the shape of a cuboid. Block 50 is, for example, bonded to block 46, for example by a glue layer.

In the example of FIG. 1, the walls of cavity 16 are substantially vertical, that is, orthogonal to the upper surface of base 12. Thus, block 50 has horizontal dimensions, for example, substantially identical to those of block 46.

Preferably, block 50 has horizontal dimensions smaller than or equal to those of block 46. In other words, block 50 preferably only rests on block 46 and does not rest on the resin of level N1. More generally, in the method of FIGS. 4A to 4D, each block of a level forming wall 14 preferably only rests on the block of the level on which it is formed. In other words, each block corresponding to a given level of the wall entirely covers the blocks corresponding to the levels located between said given level of the wall and the base.

In the example of FIG. 1, wall 14 comprises two levels. According to other embodiments, wall 14 may comprise a larger number of levels. The steps of FIGS. 4A and 4B are then repeated on the previously-manufactured level, to form all the levels of the walls. Each level corresponding to a level of wall 14 comprises a block, such as blocks 46 to 50 at the location of cavity 16 in this level. Each block is, for example, bonded to the block on which it rests, for example, by a glue layer, to ensure that the block remains at the desired location of the cavity. The stack of blocks is for example bonded to plate 44.

FIG. 4D shows another step of an implementation mode of a method of manufacturing the embodiment of FIG. 1. FIG. 4D shows the forming of base 12.

In the example of FIG. 1, the base is entirely made of resin. The base can thus considered as a single level. Levels N3 and N4 are thus entirely made of resin and can be simultaneously formed.

During this step, a resin layer 52 is formed on the last manufactured level of wall 14, that is, level N2 in the example of FIG. 4D. The resin is, for example, in liquid form. The resin is then heated so that it becomes solid. The thickness of layer 52 is at least equal to the thickness of base 12. Layer 52 is, for example, then thinned, for example by a chemical-mechanical polishing process, so that layer 52 is substantially planar and has a thickness substantially equal to the thickness of base 12.

The method then comprises a step of removal of plate 44 and of blocks 46 and 50. In the case where blocks 46 and 50 are bonded to plate 44, the blocks are removed by the removal of the plate.

As a variant, the method may comprise, after the removal of the plate, a step of etching of blocks 46 and 50. The blocks are preferably made of a material capable of being selectively etched over the material of tracks 18 and vias 20 and of the resin.

As a variant, blocks 46 and 50 may be made of copper. Blocks 46 and 50 are, for example, formed by the method of growth of tracks 18 and of vias 20. Blocks 46 and 50, tracks 18, and vias 20 are, for example, formed simultaneously. The method then comprises a step of forming of a mask protecting the tracks 18 and the vias 20 which were in contact with the plate, and then a step of etching of blocks 46 and 50.

As a variant, blocks 46 and 50 may correspond to a portion of plate 44. Thus, plate 44 may comprise a protruding portion having the shape and the dimensions of cavity 16. Tracks 18 and vias 20, as well as the resin layers, are placed around the protruding portion.

It could have been chosen to form a stack of layers, for example, insulating layers, for example comprising conductive tracks and vias, and then to etch the cavity in the stack of layers. However, such a method would not enable to control as precisely the dimensions of the cavity. Further, such a method does not enable to form deep cavities with current etching techniques.

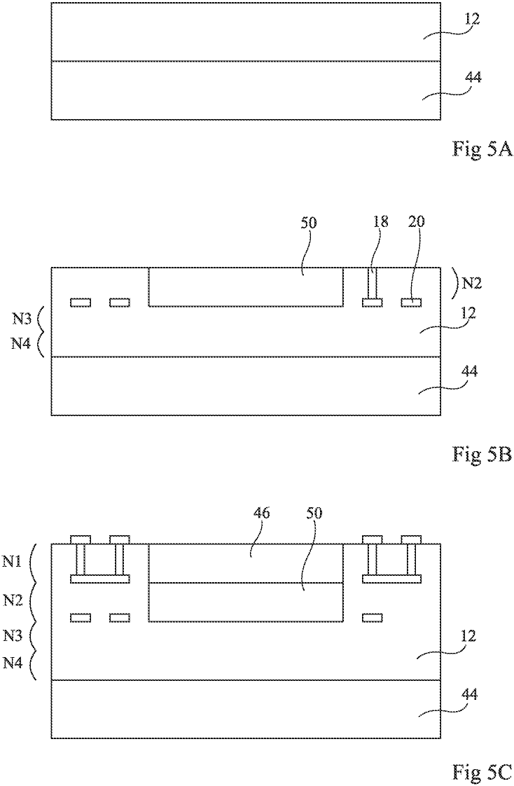

FIGS. 5A to 5C show steps, preferably successive, of an implementation mode of another method of manufacturing the embodiment of FIG. 1. Step 5A shows the forming of base 12. Steps 5B and 5C show the forming of wall 14. Although FIGS. 5A to 5C show the forming of a single carrier 10, the method enables, for example, simultaneous production of a plurality of carriers 10.

The method of FIGS. 5A to 5C mainly differs from the method of FIGS. 4A to 4D in that base 12 is formed before wall 14. Thus, the base is formed in contact with plate 44 before the forming of the wall.

FIG. 5A shows a step of another implementation mode of a method of manufacturing the embodiment of FIG. 1.

FIG. 5A shows the forming of base 12. In the example of FIG. 5A, the base is entirely made of resin. Base 12 can thus be considered as a single level made of resin.

During this step, a resin layer, for example, liquid, is formed on plate 44. The resin is then heated so that it becomes solid. The thickness of the resin layer is at least equal to the thickness of base 12. The resin layer is, for example, then thinned, for example by a chemical-mechanical polishing method, so that the resin layer is substantially planar and has a thickness substantially equal to the thickness of base 12. The resin layer then forms base 12. The levels N3 and N4 of FIG. 1 are thus formed.

FIG. 5B shows another step of another implementation mode of a method of manufacturing the embodiment of FIG. 1.

During this step, level N2 is formed on base 12. More precisely, the step of FIG. 4C is carried out on base 12. In other words, the step of FIG. 5B comprises the forming, by growth on base 12, of the tracks 18 and of the vias 20 of level N2, the placing of block 50 at the location of cavity 16 in level N2, the forming of the resin layer of level N2. Block 50 is, for example, bonded to base 12, for example by a glue layer, not shown.

FIG. 5C shows another step of another implementation mode of a method of manufacturing the embodiment of FIG. 1.

During this step, level N1 is formed on level N2. More precisely, the step of FIG. 4C is carried out on base 12. In other words, the step of FIG. 5C comprises the forming, by growth on level N2, of the tracks 18 and of the vias 20 of level N1, the placing of block 46 at the location of cavity 16 in level N1, the forming of the resin layer of level N1. Block 46 is, for example, bonded to level N2, preferably to block 50, for example by a glue layer, not shown.

Preferably, block 46 entirely covers block 50. More generally, in the method of FIGS. 5A to 5C, each block of a level forming wall 14 entirely covers the block of the level on which it is formed. In other words, each block corresponding to a given level of the wall entirely covers the blocks corresponding to the levels located between said given level of the wall and the base.

The method then comprises a step of removal of plate 44 and of blocks 46 and 50.

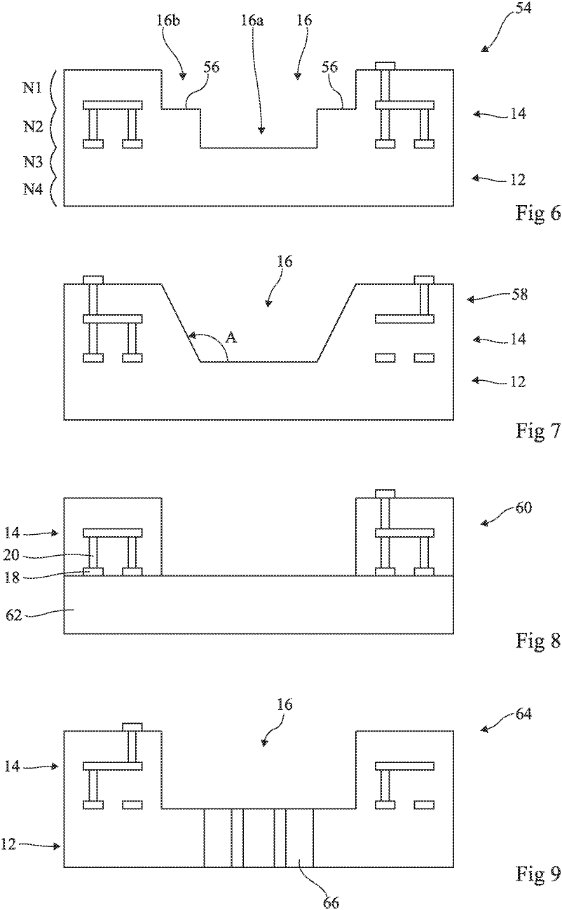

FIG. 6 shows another embodiment of an electronic chip carrier 54.

Carrier 54 differs from the carrier 10 of FIG. 1 in that cavity 16 comprises steps 56 between sidewalls. In other words, cavity 16 comprises a lower portion 16a with lower sidewalls and an upper portion 16b with upper sidewalls, the steps 56 joining the lower and upper sidewalls. Lower portion 16a is closer to base 12 than upper portion 12b.

In the example of FIG. 6, portion 16a is located in level N2 and portion 16b is located in level N1. More generally, portion 16a may correspond to a portion of the cavity located in one or a plurality of levels of wall 14. Similarly, portion 16b may correspond to a portion of the cavity located in one or a plurality of levels of wall 14. Thus, wall 14 is a stack of levels comprising, from base 12, the level(s) corresponding to the portion 16b of the cavity, and then the level(s) corresponding to the portion 16b of cavity 16.

The horizontal dimensions of lower portion 16a are smaller than the horizontal dimensions of portion 16b. A portion of the resin of the level(s) corresponding to portion 16a is located in front of portion 16b, thus forming step 56. Preferably, step 56 is located over the entire periphery of cavity 16. Conductive tracks, not shown, are for example formed on step 56. The conductive racks, not shown, are for example coupled to tracks 18 and vias 20.

Carrier 54 is particularly adapted to forming part of a package of an optoelectronic device such as shown in FIG. 3. Indeed, it is then possible to place a plate, for example, a glass plate, on step 56. The plate is then laterally maintained in place by wall 14 between the upper sidewalls.

The method of manufacturing carrier 54 differs from the methods described in relation with FIGS. 4A to 4D and 5A to 5C in that the horizontal dimensions of blocks 46 and 50 are different. More precisely, the horizontal dimensions of block 50 are smaller than the horizontal dimensions of block 46.

FIG. 7 shows another embodiment of an electronic chip carrier 58.

Carrier 58 differs from the carrier of FIG. 1 in that the sidewalls of cavity 16, that is, the internal sides of wall 14, are inclined. In other words, at least one of the sidewalls of cavity 16 forms an angle A different from 90° with the back of cavity 16, that is, the central portion of the upper surface of base 12.

In the example of FIG. 7, cavity 16 widens away from base 12. Thus, at least one of the horizontal dimensions, that is, in a plane parallel to the back of cavity 16, of the cavity increases with the distance from base 12. The angle A between the bottom of the cavity and at least one of the sidewalls of the cavity is then greater than 90°, for example, in the range from 95° to 135°.

As a variant, cavity 16 may narrow away from base 12. Thus, at least one of the horizontal dimensions, that is, in a plane parallel with the back of cavity 16, of cavity 15 decreases with the distance from base 12. The angle A between the back of the cavity and at least one of the sidewalls of cavity 16 is then smaller than 90°, for example, in the range from 45° to 85°.

Such a carrier is, for example, useful in a package of an optoelectronic device. Indeed, the rays are then filtered during their travel to an integrated circuit chip located at the back of the cavity.

The method of manufacturing carrier 58 differs from the methods described in relation with FIGS. 4A to 4D and 5A to 5C in that blocks 46 and 50 have at least one inclined sidewall.

FIGS. 6 and 7 illustrate two variants where the cavities have different shapes, advantageous in certain applications. In other variants, the cavities may have still other shapes. The shape of the cavity depending on the shape of the different blocks placed at each level during the manufacturing method at the location of the cavity.

FIG. 8 shows another embodiment of an electronic chip carrier 60.

Carrier 60 differs from the carrier 10 of FIG. 1 in that wall 14 is located on a base 62 different from base 12. More precisely, base 62 is made of materials different from the materials of base 12. For example, base 62 is a stack of layers comprising resin layers comprising glass fibers and conductive layers.

The method of manufacturing carrier 60 differs from the methods described in relation with FIGS. 4A to 4D and 5A to 5C in that the method does not comprise the forming of base 12. Further, wall 14 is directly formed on base 62. Plate 44 is thus not used. Since wall 14 and the element on which it is formed, here base 62, are not separated, the method of FIGS. 4A to 4D cannot be used. Indeed, in the method of FIGS. 4A to 4D, plate 44 and the wall are separated to remove blocks 46 and 50.

The upper layer of base 62, that is, the layer closest to wall 14 and the layer having wall 14 formed thereon, comprises at least metal portions, to allow the growth of tracks 18 and of vias 20. For example, said upper layer may be an entirely metallic layer.

FIG. 9 shows another embodiment of an electronic chip carrier 64.

Carrier 64 differs from the carrier 10 of FIG. 1 in that base 12 comprises vias 66. Vias 66 are located in front of cavity 16. Vias 66 cross base 12. In other words, vias 66 extend from the lower surface of base 12 to the central portion of the upper surface of base 12. An end of each via is flush with the central portion of the upper surface of base 12, that is, the back of cavity 16. Another end of each via 66 is flush with the upper surface of base 12.

Preferably, an integrated circuit chip, not shown, is intended to be placed in cavity 16, in contact, by its lower surface, with vias 66. Preferably, all vias 66 are in contact with the chip. Vias 66 are, for example, used to dissipate the heat from the integrated circuit chip. The vias are then, for example, wider than vias 20 to allow a better heat dissipation.

As a variant, at least some of vias 66 may be used to electrically connect the chip located in cavity 16 to external circuits.

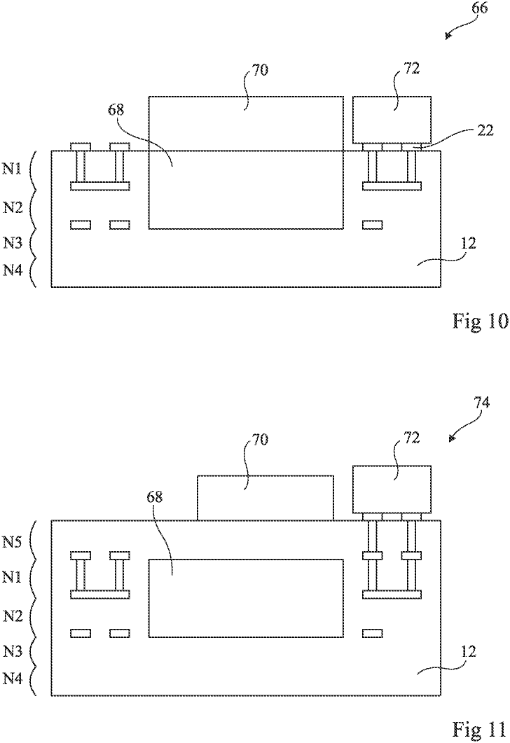

FIG. 10 shows another embodiment of an electronic chip carrier 66.

Carrier 66 differs from the carrier 10 of FIG. 1 in that cavity 16 is filled with a block 68, for example, a resin block, preferably a resin different from the resin forming the base. For example, the resin of block 68 is a resin having a permittivity better adapted to the propagation of radio frequency waves than the resin forming the base. The base, for example, comprises an antenna or another transmit and/or receive circuit.

In the example of FIG. 10, wall 14 preferably has a height greater than or equal to the height of the resin located in the cavity.

The carrier 66 of FIG. 10 may for example be used as a carrier for integrated circuit chips 70 and 72. Chip 70 is, for example, placed on resin 68. Chip 70 is, for example, bonded to the resin by a bonding layer. Chip 72 is, for example, located on top of and in contact with tracks 22.

The method of manufacturing carrier 66 comprises, for example, the steps described in relation with FIGS. 4A to 4D or 5A to 5C. The method comprises, after the removal of blocks 46 and 50, the forming of block 68, that is, the deposition of a resin layer sufficiently thick to fill the cavity. The resin layer is then thinned to remove the portions located outside of the cavity. In the case of the method of FIGS. 5A to 5C, the forming of block 68 is preferably performed before the removal of plate 44.

FIG. 11 shows another embodiment of an electronic chip carrier 74.

Carrier 74 differs from the carrier 66 of FIG. 10 in that carrier 74 comprises a level N5. Level N5 is located on level N1. Level N5 preferably entirely covers level N1 and particularly covers block 68. Block 68 is thus entirely buried in levels N1 to N5. Level N5 is made of the same resin as levels N1 to N4. Level N5, for example, comprises tracks 20 and vias 22, like levels N1 to N4.

The carrier 74 of FIG. 11 may, for example, be used as a carrier for chips 70 and 72. Chip 70 is, for example, placed on level N5, for example, in front of resin 68. Chip 70 is, for example, bonded to level N5 by a bonding layer. Chip 72 is, for example, located on top of and in contact with tracks 22.

An advantage of the described embodiments is that they allow a better control of the cavity dimensions.

Another advantage of the described embodiments is that they allow the forming of carriers having a cavity of large dimensions.

Another advantage of the described embodiments is that they enable to obtain a black carrier, opaque to the operating wavelengths.

Another advantage of the described embodiments is that they enable to obtain a more solid carrier, which does not risk delaminating.

Another advantage of the described embodiments is that, since the cavity is not etched, it is possible to form a cavity having various shapes.

Another advantage of the described embodiments is that it is possible to form conductive vias and tracks having various shapes.

Various embodiments and variants have been described. Those skilled in the art will understand that certain features of these various embodiments and variants may be combined, and other variants will occur to those skilled in the art. In particular, although the previously-described carriers comprise a single cavity, other carriers may comprise a plurality of cavities. Said cavities may be, according to an embodiment, located on the same side of the structure with respect to the base.

According to another embodiment, the cavities may be on the two opposite sides of the base. Thus, the method of manufacturing such an embodiment would combine the methods of FIGS. 4A to 4D and 5A to 5C. In other words, the method would comprise, in this order, the forming, on the plate, of levels of a first wall comprising blocks at the location of the cavities, the forming of the base on the levels of the first wall, and then the forming of a second wall on the base, comprising blocks at the location of the cavities, and the removal of the plate and of the blocks from both sides.

Finally, the practical implementation of the described embodiments and variations is within the abilities of those skilled in the art based on the functional indications given hereabove.

1. A method of manufacturing an integrated circuit chip carrier, comprising:
forming a wall surrounding a cavity, wherein the wall comprises one or more first levels, by:
at each first level, forming a layer of a first resin around a block, wherein the block is made of a material different from the first resin; and
removing each block to open the cavity.

2. The method according to claim 1, comprising:
forming of a base of the integrated circuit chip carrier having the wall resting thereon;
wherein forming the base comprises forming one or more second levels by:
at each second level, forming a layer of the first resin extending in front of the location of the cavity.

3. The method according to claim 2, wherein forming of the base further comprises forming metal vias crossing the base in front of the cavity.

4. The method according to claim 2, wherein forming each first level comprises growing metal tracks and metal vias.

5. The method according to claim 4, wherein the block is made of a same material as the metal tracks and metal vias.

6. The method according to claim 2, wherein the one or more first levels are formed on a plate.

7. The method according to claim 6, wherein the one or more second levels are formed on the plate before the one or more first levels.

8. The method according to claim 6, wherein the plate forms the base of the carrier.

9. The method according to claim 6, wherein the one or more first levels are formed on the plate before the one or more second levels.

10. The method according to claim 9, wherein the block is formed by a portion of the plate.

11. The method according to claim 1, wherein the wall comprises a plurality of first levels and the block for each first level has same horizontal dimensions.

12. The method according to claim 1, wherein at least one sidewall of the block is inclined with respect to a plane of a back of the cavity.

13. The method according to claim 1, wherein the block for one of the first levels closest to the back of the cavity has at least one horizontal dimension smaller than the block for another of the first levels further from the back of the cavity to define, within the cavity, a step.

14. The method according to claim 1, further comprising filling of the cavity with a second resin different from the first resin.

15. A device obtained by the method according to claim 1, wherein the cavity has a height greater than 30 µm.

16. A method of manufacturing an integrated circuit chip carrier, comprising:
providing a first block at a surface of a plate;
forming first metal tracks and first metal vias on the surface of the plate spaced from the first block;
forming a first layer of resin around the first block and first metal tracks and first metal vias;
mounting a second block to a surface of the first block;
forming second metal tracks and second metal vias on a surface of the first layer of resin spaced from the second block;
forming a second layer of resin around the second block and second metal tracks and second metal vias;
forming a base layer covering the second layer of resin and the second block; and
removing the plate, the first block and the second block to open a cavity having sidewalls delimited by the first and second layers of resin and a bottom defined by a surface of the base layer.

17. The method of claim 16, wherein sidewalls of the first and second blocks are inclined with respect to the surface of the plate.

18. The method of claim 16, wherein the first and second blocks have same dimensions.

19. The method of claim 16, wherein the first block has a first horizontal dimension larger than a second horizontal dimension of the second block, and wherein the sidewalls delimited by the first and second layers of resin include a step defined by a difference in first and second horizontal dimensions.

20. The method of claim 16, further comprising forming vias extending through the base layer.

21. The method of claim 16, further comprising filling the cavity with a resin different from a resin of the first and second layers of resin.

22. The method of claim 21, further comprising forming a third layer of resin covering the resin filling the cavity.

23. The method of claim 16, wherein providing the first block at the surface of the plate comprises mounting the first to the surface of the plate.

24. The method of claim 16, wherein providing the first block at the surface of the plate comprises forming the plate to integrally include the first block.

25. A method of manufacturing an integrated circuit chip carrier, comprising:
forming a base layer covering a plate;
mounting a first block to a surface of base layer;
forming first metal tracks and first metal vias on the surface of the base layer spaced from the first block;
forming a first layer of resin around the first block and first metal tracks and first metal vias;
mounting a second block to a surface of the first block;
forming second metal tracks and second metal vias on a surface of the first layer of resin spaced from the second block;
forming a second layer of resin around the second block and second metal tracks and second metal vias; and
removing the first block and the second block to open a cavity having sidewalls delimited by the first and second layers of resin and a bottom defined by a surface of the base layer.

26. The method of claim 25, wherein sidewalls of the first and second blocks are inclined with respect to the surface of the plate.

27. The method of claim 25, wherein the first block has a first horizontal dimension smaller than a second horizontal dimension of the second block, and wherein the sidewalls delimited by the first and second layers of resin include a step defined by a difference in first and second horizontal dimensions.

28. The method of claim 25, wherein the first and second blocks have same dimensions.

29. The method of claim 25, further comprising forming vias extending through the base layer.

30. The method of claim 25, further comprising filling the cavity with a resin different from a resin of the first and second layers of resin.

31. The method of claim 30, further comprising forming a third layer of resin covering the resin filling the cavity.

32. The method of claim 25, further comprising removing the plate.
